(19) United States
(12) Patent Application Publication
(10) Pub. No.: US 2008/0137701 A1
(43) Pub. Date: Jun. 12, 2008

(54) Gallium Nitride Based Semiconductor Device with Reduced Stress Electron Blocking Layer

(76) Inventor: Joseph Michael Freund, Fogelsville, PA (US)

Correspondence Address: Ryan, Mason & Lewis, LLP, 90 Forest Avenue, Locust Valley, NY, 11560, US

(21) Appl. No.: 11/609,372

(22) Filed: Dec. 12, 2006

(51) Int. Cl. H01S 5/323; H01L 33/00; H01L 31/0352

(52) U.S. Cl. 372/45.011; 257/13; 438/31; 438/69; 257/14; 257/E33.008; 257/E31.033

(57) ABSTRACT

A semiconductor device comprises an active layer and a cladding layer. An electron blocking layer is at least partially disposed in a region between the active layer and the cladding layer and is configured to form a potential barrier to a flow of electrons from the active layer toward the cladding layer. The electron blocking layer comprises two elements from Group III of the periodic table and an element from Group V of the periodic table. One of the two elements from Group III of the periodic table has a concentration profile with a first portion that gradually increases in concentration in a direction away from the active layer toward the cladding layer and a second portion that gradually decreases in concentration between the first portion and the cladding layer.

### CROSS REFERENCE TO RELATED APPLICATIONS

A related patent application is U.S. patent application Ser. No. 11/419,592, entitled “Gallium Nitride Based Semiconductor Device with Electron Blocking Layer,” which is commonly assigned herewith and incorporated by reference herein.

### FIELD OF THE INVENTION

This invention relates generally to semiconductor devices and, more particularly, to gallium nitride (GaN) based semiconductor devices.

### BACKGROUND OF THE INVENTION

GaN based blue-violet semiconductor lasers are likely to have far reaching technological and commercial effects. These semiconductor lasers emit near 400 nanometers, about half the wavelength of typical gallium arsenide (GaAs) based semiconductor lasers. The shorter wavelengths allow GaN based semiconductor lasers to achieve higher spatial resolution in applications such as optical storage and printing. Blu-ray DiSC™ and High Density Digital Versatile Disc (HD-DVD™) are, for example, next-generation optical disc formats that utilize blue-violet semiconductor lasers for the storage of high-definition video and data.

GaN based blue-violet semiconductor lasers typically comprise a multilayer semiconductor structure formed on a substrate (e.g., sapphire), and electrical contacts that facilitate the application of an electrical voltage to a portion of the multilayer structure. FIG. 1 shows a sectional view of a conventional GaN based semiconductor laser 100, while FIG. 2 shows the relative conduction band levels, Ec, of various constituent layers and sublayers under typical operating bias conditions. The semiconductor laser comprises a sapphire substrate 110, an n-type gallium nitride (n-GaN) base layer 120, an n-type aluminum gallium nitride (n-AlGaN) cladding layer 130 and an n-side undoped GaN waveguide layer 140. A multiple quantum well (MQW) active layer 150 is formed on top of the n-side waveguide layer. These quantum wells comprise three indium gallium nitride (InGaN) well sublayers 152 separated by GaN barrier sublayers 154. A p-side undoped GaN waveguide layer 160 followed by a p-type stressed layer superlattice (SLS) cladding layer 170 are formed on the MQW active layer. The SLS cladding layer comprises alternating sublayers of p-AlGaN and p-GaN, 172 and 174, respectively. A p-type aluminum gallium nitride (p-AlGaN) electron blocking layer 180 is formed inside the p-side waveguide layer.

Two electrical contacts 190, 195 are operative to allow the application of electrical bias to the semiconductor laser 100. The applied electrical bias causes electrons and holes to be injected into the MQW active layer 150. Some of these injected electrons and holes are trapped by the quantum wells and recombine, generating photons of light. By reflecting some of the generated light from facets (not shown) formed at two opposing vertical surfaces of the semiconductor laser, some photons are made to pass through the MQW active layer several times, resulting in stimulated emission of radiation.

The waveguide layers 140, 160 form an optical film waveguide in the semiconductor laser 100 and serve as local reservoirs for electrons and holes for injection into the MQW active layer 150. The optical film waveguide, in turn, is completed by cladding layers 130, 170 which have higher indices of refraction than the waveguide layers. The cladding layers act to further restrict the generated light to the MQW active layer of the semiconductor laser.

As shown in FIG. 2, the electron blocking layer 180 in the semiconductor laser 100 is configured to have a relatively high conduction band level, Ec. The electron blocking layer, thereby, forms a potential barrier that acts to suppress the flow of electrons from the MQW active layer 150. Advantageously, this reduces the threshold current of the semiconductor laser (the minimum current at which stimulated emission occurs), allowing for a higher maximum output power. Electron blocking layers are described for use in GaAs based semiconductor lasers in, for example, U.S. Pat. No. 5,448,585 to Belenky et al., entitled “Article Comprising a Quantum Well Laser,” which is incorporated herein by reference. Nevertheless, the implementation of conventional electron blocking layers in GaN based semiconductor lasers is problematic. Electron blocking layers located between the MQW active layer and one of the waveguide layers have been shown to cause excessive physical stress on the MQW active layer which may, in turn, cause cracking.

As a response, attempts have been made to move the electron blocking layer away from the MQW active layer. Asano et al. in “100-mV Kink-Free Blue-Violet Laser Diodes with Low Aspect Ratio,” IEEE Journal of Quantum Electronics, Vol. 39, No. 1, January 2003, also incorporated herein by reference, for example, studied the effects of positioning p-AlGaN electron blocking layers in several different positions in p-side waveguide layers of semiconductor lasers similar to the semiconductor laser 100 shown in FIG. 1. Unfortunately, however, such efforts have shown limited success in reducing the physical stress in the MQW active layer. Stress induced cracking still remains an issue for GaN based semiconductor lasers.

There is, as a result, a need for a GaN based blue-violet semiconductor laser design that includes an electron blocking layer without the concomitant physical stresses on the active layer.

### SUMMARY OF THE INVENTION

An illustrative embodiment of the present invention addresses the above-identified need by allowing an electron blocking layer to be implemented in a semiconductor laser without inducing excessive physical stress in the laser's active layer.

In accordance with an aspect of the invention, a semiconductor device comprises an active layer and a cladding layer. An electron blocking layer is at least partially disposed in a region between the active layer and the cladding layer and is configured to form a potential barrier to a flow of electrons from the active layer toward the cladding layer. The electron blocking layer comprises two elements from Group III of the periodic table and an element from Group V of the periodic table. One of the two elements from Group III of the periodic table has a concentration profile with a first portion that gradually increases in concentration in a direction away from the active layer toward the cladding layer and a second portion that gradually decreases in concentration between the first portion and the cladding layer.

Consistent with the above-mentioned illustrative embodiment, the semiconductor laser may be formed from various layers and sublayers comprising doped and undoped AlGaN, GaN and InGaN. One of the constituent layers comprises a p-AlGaN electron blocking layer. The aluminum concentration profile in the p-AlGaN electron blocking layer comprises a first portion and a second portion. In the first portion, the aluminum concentration gradually increases. In the second portion, the aluminum concentration gradually decreases. Advantageously, the illustrative semiconductor laser exhibits the benefits of an electron blocking layer (e.g., lower threshold current) but does not suffer from excessive physical stress that can lead to cracking.

These and other features and advantages of the present invention will become apparent from the following detailed description which is to be read in conjunction with the accompanying figures.

### BRIEF DESCRIPTION OF THE DRAWINGS

FIG. 1 shows a sectional view of a GaN based semiconductor laser in accordance with the prior art.

FIG. 2 shows the conduction band levels of various layers and sublayers within the FIG. 1 semiconductor laser.

FIG. 3 shows a sectional view of a GaN based semiconductor laser in accordance with an illustrative embodiment of the invention.

FIG. 4 shows the conduction band levels of various layers and sublayers within the FIG. 3 semiconductor laser.

FIG. 5 shows a possible variation of the conduction band levels in the FIG. 3 semiconductor laser.

FIG. 6 shows a block diagram of the FIG. 3 semiconductor laser implemented in an optical device.

FIG. 7 shows a sectional view of a GaN based semiconductor laser in accordance with another illustrative embodiment of the invention.

FIG. 8 shows the conduction band levels of various layers and sublayers within the FIG. 7 semiconductor laser.

### DETAILED DESCRIPTION OF THE INVENTION

The present invention will be described with reference to illustrative embodiments in accordance with aspects of the invention. Nevertheless, the invention is not limited to these particular embodiments. Numerous modifications and variations can be made to the embodiments described herein and the results will still come within the scope of this invention. For example, while the illustrative embodiments comprise semiconductor lasers, the invention also encompasses light emitting diodes, photodetectors, optical couplers and other such semiconductor devices. Therefore, no limitations with respect to the specific embodiments described herein are intended or should be inferred.

It should be noted that the term “layer” as utilized herein is intended to encompass any stratum of matter with a given function or functions within a semiconductor device. A layer may be substantially homogenous in composition or may comprise two or more sublayers with differing compositions. For ease of understanding, several layers in FIGS. 1, 3 and 7 are represented as single features when, in fact, they comprise a plurality of sublayers of differing compositions.

The term “periodic table” as used herein refers to the periodic table of the chemical elements. Group III, as used herein, comprises the elements of boron, aluminum, gallium, indium and thallium. Group V, as used herein, comprises the elements of nitrogen, phosphorus, arsenic, antimony and bismuth.

As is conventional, expressions such as “InGaN,” and “AlGaN” are not chemical formulas, but are instead merely recitations of constituent elements. Thus, for example, the expression “InGaN” is to be understood to encompass the ternary alloy InₓGa₁₋ₓN while “AlGaN” encompasses the ternary alloy AlₓGa₁₋ₓN.

The various layers and/or regions shown in the accompanying figures are not drawn to scale and one or more layers and/or regions of a type commonly used in semiconductor devices may not be explicitly shown in a given figure for ease of explanation. This does not imply that the layer(s) and/or regions(s) not explicitly shown are omitted from actual semiconductor devices comprising aspects of the invention.

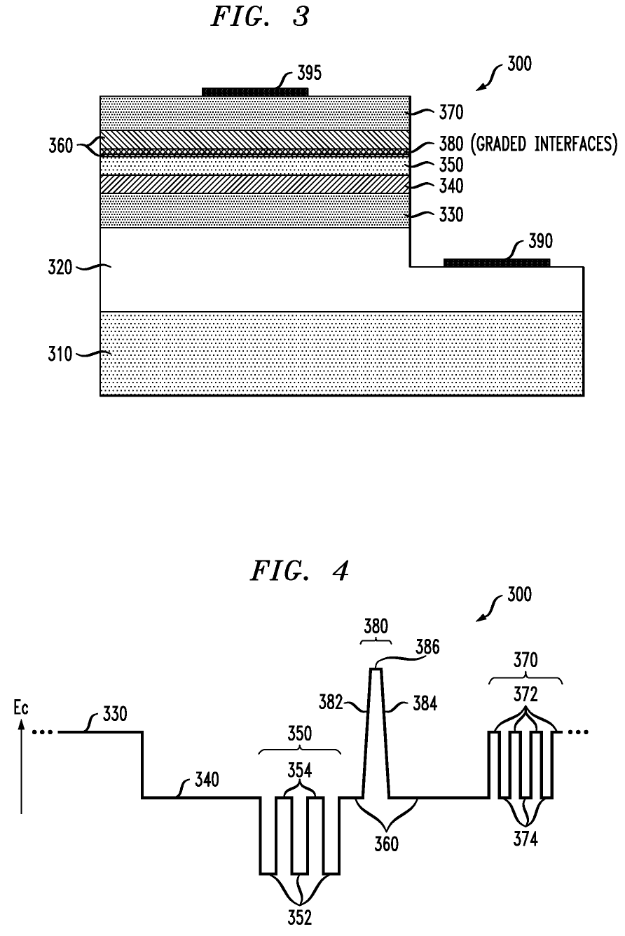

FIGS. 3 and 4 show views of a GaN based semiconductor laser 300 in accordance with an illustrative embodiment of the invention. More precisely, FIG. 3 shows a sectional view of the semiconductor laser 300, while FIG. 4 shows the relative conduction band levels, Ec, of various layers and sublayers within the FIG. 3 semiconductor laser under operating bias conditions. The semiconductor laser comprises a sapphire substrate 310, a 5,000-nanometer (nm) thick n-GaN base layer 320 and a 1,300-nm thick n-AlGaN cladding layer 330. An MQW active layer 350 is formed between a 100-nm thick n-side undoped GaN waveguide layer 340 and a 100-nm thick p-side undoped GaN waveguide layer 360. A p-type SLS cladding layer 370 is formed on the p-side waveguide layer. In addition, a p-AlGaN electron blocking layer 380 is formed inside the p-side waveguide layer. Electrical contacts 390, 395 allow an electrical bias to be applied to a portion of the semiconductor laser.

The MQW active layer 350, in turn, comprises at least one InGaN well sublayer 352. Multiple InGaN sublayers are separated by GaN barrier sublayers 354. The MQW active layer may typically comprise three InGaN well sublayers about 3.5-nm thick separated by two GaN barrier sublayers about 7-nm thick. The SLS cladding layer 370, on the other hand, comprises a large number of p-AlGaN sublayers 372 separated by p-GaN sublayers 374. The SLS cladding layer may typically comprise about 100 2.5-nm thick p-AlGaN sublayers separated by p-GaN sublayers about 2.5-nm thick. In the illustrative embodiment, the number and thickness of quantum well sublayers as well as the number and thickness of sublayers in the cladding layer can vary. In the illustrative embodiment, the n-GaN base layer 320 and the n-AlGaN cladding layer 330 are doped with a Group IV dopant, preferably silicon. In contrast, the p-AlGaN electron blocking layer 380 and the p-AlGaN and p-GaN sublayers 372, 374 are doped with a Group II dopant, preferably magnesium. It is advantageous to use a multilayer p-AlGaN/p-GaN SLS structure for the p-type cladding layer 370 rather than bulk p-AlGaN for several reasons. Firstly, the multilayer SLS structure has been shown to reduce physical stress in the cladding layer when compared to cladding layers comprising bulk p-AlGaN. Secondly, the multilayer SLS structure has been shown to comprise an enhanced hole concentration. The average hole concentration of a multilayer SLS cladding layer at room temperature may be a factor of ten higher than the concentration in bulk films (e.g., bulk p-AlGaN doped with magnesium).

The p-AlGaN electron blocking layer 380 is configured to provide a potential barrier for the flow of electrons from the MQW active layer 350 into the SLS cladding layer 370. This is achieved by configuring the composition of the electron blocking layer such that the layer has a large bandgap and, as a result, a relatively high conduction band level, Ec. The band gap of AlₓGa₁₋ₓN can be readily modified by changing the value of x. Generally, the higher the aluminum concentration (i.e., the higher the value of x), the higher is the bandgap of the material. The bandgap of AlₓGa₁₋ₓN as a function of x is described in, for example, J. F. Muth et al., “Absorption Coefficient and Refractive Index of GaN, AlN and AlGaN Alloys,” MRS Internet Journal of Nitride Semiconductor Research 4S1, G5.2 (1999), which is incorporated herein by reference. According to this reference, binary aluminum nitride (Al₁N₁), for example, has a bandgap of about 6.20 electron volts. Binary gallium nitride (Ga₁N₁), on the other hand, has a bandgap of only about 3.43 electron volts. The ternary alloy Al_{0.27}Ga_{0.73}N has a band gap of 4.00 electron volts.

In accordance with an aspect of the invention, the aluminum concentration profile in the p-AlGaN electron blocking layer 380 comprises two portions, a gradually increasing aluminum concentration portion 382 and a gradually decreasing aluminum concentration portion 384. Both portions can be seen in the conduction band profile for the electron blocking layer in FIG. 4 since, as described above, the bandgap of AlGaN correlates or tracks with aluminum concentration. The increasing aluminum concentration portion of the aluminum concentration profile gradually increases in aluminum concentration in a direction away from active layer 350 toward the cladding layer. The decreasing aluminum concentration portion gradually decreases in aluminum concentration between the increasing aluminum concentration portion and the SLS cladding layer 370. In between the increasing aluminum concentration and decreasing aluminum concentration portions of the aluminum concentration profile, the aluminum concentration reaches a plateau 386 where it remains substantially constant. In the illustrative embodiment, the increasing aluminum concentration portion and the decreasing aluminum concentration portion of the electron blocking layer each has a thickness equal to about 10 nm. The plateau also has a thickness of about 10 nm, making the electron blocking layer about 30 nm thick in total. Nevertheless, these thicknesses are merely illustrative and other thicknesses are contemplated as being within the scope of the invention.

While the electron blocking layer 380 is designed to provide a potential barrier to the flow of electrons, it should not be understood to mean that the presence of the electron blocking layer completely stops all electron flow past the layer. Instead, the electron blocking layer causes at least a substantially lower flow of electrons at device operating temperature and bias when compared to the flow of electrons observed in an otherwise identical semiconductor laser that does not comprise the electron blocking layer. The electron blocking layer preferably has a potential barrier that is at a level of about 50 millielectron volts higher than the conduction band level of the p-side waveguide layer 360. The potential barrier is of sufficient thickness not to suffer from significant amounts of electron tunneling and leakage. Typically, the potential barrier will be at least about 10 nm thick.

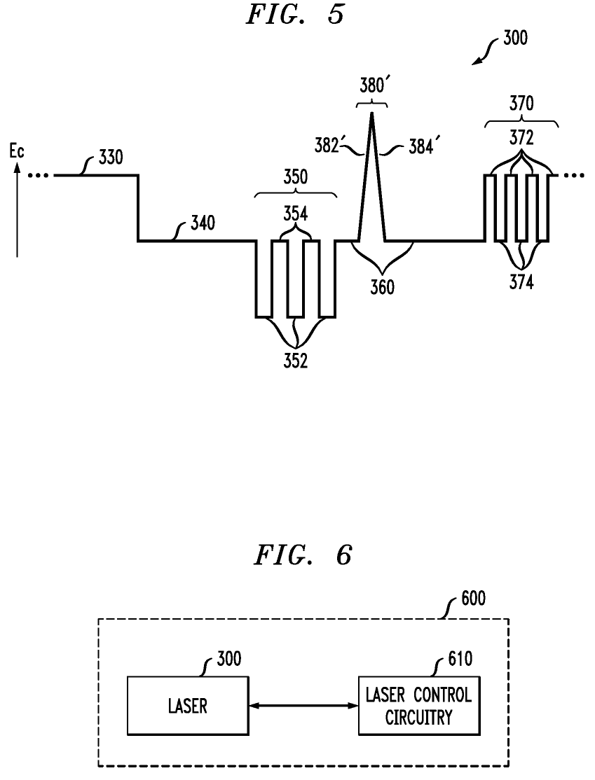

FIG. 5 shows a variation on the illustrative embodiment shown in FIGS. 3 and 4. In FIG. 5, an increasing aluminum concentration portion 382′ and a decreasing aluminum concentration portion 384′ of the aluminum concentration profile in the p-AlGaN electron blocking layer 380′ are abutted against one another, without a plateau therebetween, causing the increasing aluminum concentration portion and the decreasing aluminum concentration portion to form an inflection point at the maximum aluminum concentration value rather than having a concentration plateau between the two portions. One skilled in the art will recognize that such a variation may be desirable in order to fabricate a thinner electron blocking layer.

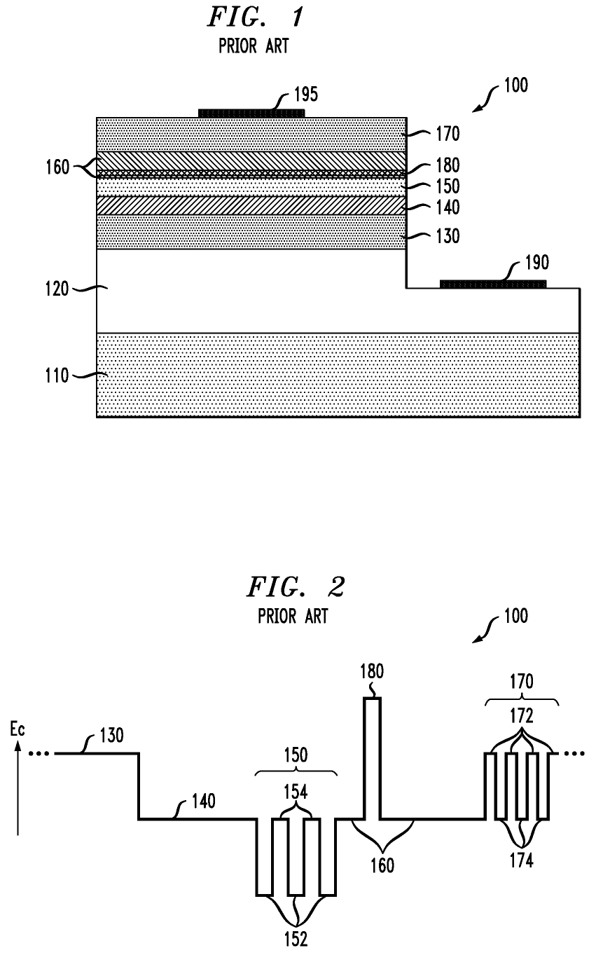

Advantageously, configuring the electron blocking layer 380 in accordance with aspects of the invention allows the electron blocking layer to be implemented in the semiconductor laser 300 without inducing excessive physical stresses in the laser. Generally, much of the physical stress in GaN based semiconductor lasers is induced by lattice mismatches between adjacent layers and sublayers. By configuring the electron blocking layer in the manner shown in FIGS. 3, 4 and 5, a progressive transition from lower aluminum concentration p-AlGaN to higher aluminum concentration p-AlGaN and then again to lower aluminum concentration p-AlGaN is created. This reduces the severity of lattice mismatches between these adjacent layers and, thereby, reduces the overall physical stress in the semiconductor laser when compared to conventional semiconductor lasers like the semiconductor laser 100 shown in FIGS. 1 and 2.

It should be noted that the above-described design of the semiconductor laser 300 is illustrative and that many other designs would still come within the scope of this invention. For example, it may be advantageous to form the MQW active layer 350 from alternating sublayers of InGaN of a first composition and InGaN of second composition, or to form the layers and sublayers constituting the semiconductor laser with thicknesses very different from those explicitly described herein. As another example, it may be advantageous to form the electron blocking layer 380 from a ternary III-V compound other than AlGaN such as, but not limited to, indium gallium phosphide (InGaP). The SLS cladding sublayers 372, 374 may then comprise, for example, InGaP and indium phosphide (InP), respectively. If InGaP is utilized for the electron blocking layer, the concentration of indium may be varied to produce conduction band profiles similar to those shown in FIGS. 4 and 5. The number and thickness of quantum well sublayers can vary, as can the number and thickness of sublayers in the cladding layer. These and other variations on the illustrative embodiments will be evident to those skilled in the art.

Moreover, while the aluminum concentration profiles of the electron blocking layers 380 and 380′ in the particular illustrative embodiments shown in FIGS. 4 and 5, respectively, gradually increase and decrease in a linear fashion, the invention is not limited thereto. Instead, it may be advantageous because of tooling or other considerations to form electron blocking layers with Group III elements having concentration profiles that gradually increase and decrease in non-linear fashions. It may be advantageous to form, for example, electron blocking layers having aluminum concentration profiles that gradually increase and decrease in a step-wise or in a parabolic manner. Such alternative configurations are contemplated and would still come within the scope of this invention.

FIG. 6 shows a block diagram of the implementation of the semiconductor laser 300 in an optical device 600 in accordance with an illustrative embodiment of the invention. The optical device may be, for example, an optical disc drive with high density data read/write capabilities or, alternatively, a component in a fiber optic communication system. The operation of the semiconductor laser in the optical device is largely conventional and will be familiar to one skilled in the art. Moreover, the operation of semiconductor lasers is described in detail in a number of readily available references such as, for example, P. Holloway et al., Handbook of Compound Semiconductors, William Andrews Inc., 1996, and E. Kapon, Semiconductor Lasers II, Elsevier, 1998, which are incorporated herein by reference.

As described earlier, the semiconductor laser 300 is powered by applying an electrical control bias across the electrical contacts 390, 395. Generally, the greater the amount of control bias applied to the electrical contacts, the greater the amount of stimulated emission that occurs in this MQW active layer 350 of the semiconductor laser and the greater the amount of light output. In the optical device 600, it is control circuitry 610 that applies the control bias to the semiconductor laser's electrical contacts. Precise laser output power may optionally be maintained by use of one or more monitor photodiodes that measure the output power of the semiconductor laser and feed this measurement back to the control circuitry. The control circuitry may be a discrete portion of circuitry within the optical device or may, in contrast, be integrated into the device's other circuitry.

The semiconductor laser 300 is preferably formed by sequentially depositing the layers shown in FIG. 3, from bottom to top as shown in the figure, using conventional semiconductor processing techniques that will be familiar to one skilled in that art. Because of the large lattice mismatch (about 15%) between sapphire and GaN, the n-GaN base layer 320 is preferably formed on the sapphire substrate 310 using what is commonly referred to as “epitaxial lateral overgrowth” (ELO). In the ELO process, the sapphire is first coated with a thin silicon dioxide mask that is patterned to expose repeating stripes of the sapphire surface that run in the GaN <1100> direction. The n-GaN base layer is then deposited by metal organic chemical vapor deposition (MOCVD) on the exposed sapphire. During deposition, the n-GaN coalesces to form a high quality bulk film with few defects.

The remaining films may then be deposited sequentially using steps comprising MOCVD. The MOCVD deposition technique (also called metal oxide vapor phase epitaxy) is conventionally used in semiconductor processing and will be familiar to one skilled in that art. In MOCVD, the film stack onto which deposition is to occur is exposed to organic compounds (i.e., precursors) containing the required chemical elements. For example, metal organic compounds such as trimethyl gallium or trimethyl aluminum, in combination with reactants such as ammonia, may be utilized. The process consists of transporting the precursors via a carrier gas to a hot zone within a growth chamber. These precursors either dissociate or react with another compound to produce thin films. Dopant reactants may be added to form doped films.

Reactors are commercially available for the MOCVD of the compound III-V materials described herein. Veeco Instruments Inc. (corporate headquarters in Woodbury, N.Y.), for example, produces and markets such reactors for both research and development and commercial semiconductor device manufacturing. What is more, one skilled in the art will recognize how to form the aluminum concentration profile in the p-AlGaN electron blocking layer 380. During the MOCVD growth sequence, for example, the aluminum precursor (e.g., trimethyl aluminum) may be gradually increased as deposition occurs to produce the increasing aluminum concentration portion 382. Subsequently, also during the MOCVD growth sequence, the aluminum precursor may be gradually reduced to form the decreasing aluminum concentration portion 384.

It should be noted, however, that the invention is not limited to the deposition of the materials by MOCVD. Molecular beam epitaxy (MBE) is also capable of forming compound III-V materials like those described herein. In MBE, materials are deposited as atoms or molecules in abeam of gas onto the substrate. Typically, each material is delivered in a separately controlled beam, so the choice of elements and their relative concentrations may be adjusted for any given layer, thereby defining the composition and electrical characteristics of that layer. Beam intensity is adjusted for precise control of layer thickness, uniformity and purity. Accordingly, semiconductor lasers comprising aspects of the invention formed in whole or in part by MBE or other methods other than MOCVD would still fall within the scope of the invention.

After forming the film stack, a portion of the film stack is removed using conventional photolithography and reactive ion etching techniques so that the electrical contact 390 can be placed in contact with the n-GaN base layer 320. The electrical contacts 390, 395 (e.g., alloys comprising platinum and gold) are then deposited on the exposed n-GaN base layer and on top of the SLS cladding layer 380 by conventional metal evaporation. The multilayer structure is then cleaved to form a discrete semiconductor laser device and, subsequently, facets are formed on two opposing vertical surfaces of the semiconductor laser 300 to act as partially reflective mirrors. The facets may be coated with an anti-reflective film to precisely control the reflectivity of these mirrors.

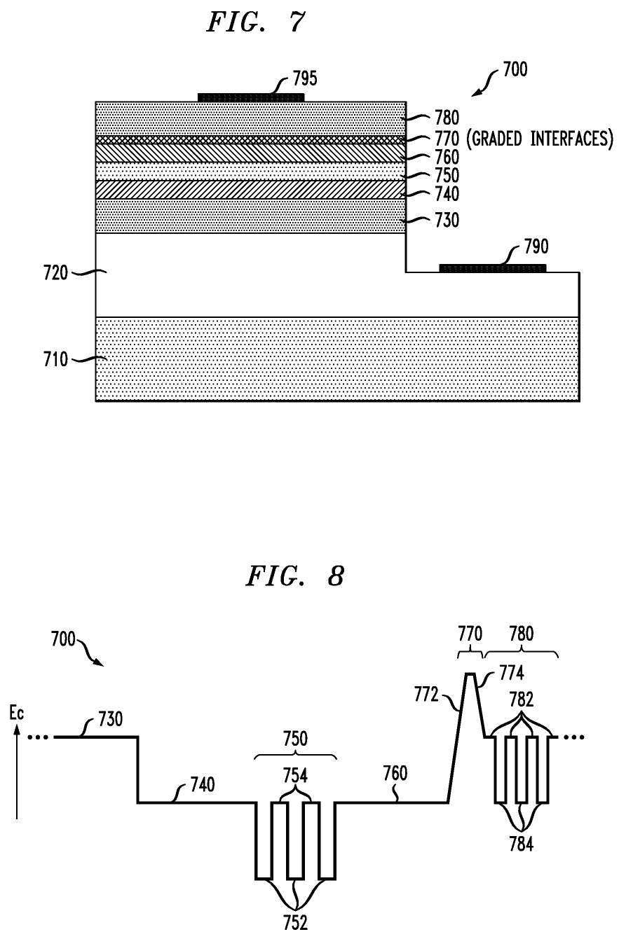

It should be noted that an electron blocking layer need not be positioned within a p-side waveguide layer for a semiconductor laser to fall within the scope of the invention. The electron blocking layer may instead adjoin the MQW active layer or adjoin the SLS cladding layer. FIG. 7, for example, shows a sectional view of the semiconductor laser 700 in accordance with another illustrative embodiment of the invention. FIG. 8, moreover, shows the relative conduction band levels, Ec, of various layers and sublayers within the semiconductor laser under operating bias conditions. This semiconductor laser comprises a sapphire substrate 710, a 5,000-nanometer (nm) thick n-GaN base layer 720 and a 1,300-nm thick n-AlGaN cladding layer 730. An MQW active layer 750 is formed between a 100-nm thick n-side undoped GaN waveguide layer 740 and a 100-nm thick p-side undoped GaN waveguide layer 760. A p-AlGaN electron blocking layer 770 is formed on the p-side waveguide layer, followed by a p-type SLS cladding layer 780 formed on the electron blocking layer. Electrical contacts 790, 795 allow an electrical bias to be applied to a portion of the semiconductor laser.

The p-AlGaN electron blocking layer 770 in the semiconductor laser 700 is disposed adjacent to the SLS cladding layer 780. An increasing aluminum concentration portion 772 of the electron blocking layer gradually increases in aluminum concentration in a direction away from active layer 350 toward the cladding layer while a decreasing aluminum concentration portion 774 gradually decreases in aluminum concentration between the increasing aluminum concentration portion and the SLS cladding layer. Advantageously, configuring the semiconductor laser in this way may even further reduce physical stresses in the semiconductor laser. In addition to reducing physical stresses induced from lattice mismatches by introducing the aluminum concentration profile into the electron blocking layer, the electron blocking layer in this illustrative embodiment is physically separated from the MQW active layer 750. The physical separation is a sufficient distance to reduce the likelihood of defects induced in the MQW active layer by physical stresses resulting from the electron blocking layer. A typical distance the electron blocking layer is separated from the MQW active layer to reduce the likelihood of stress induced defects in the semiconductor laser is about 50 nm.

It should also again be emphasized that, although illustrative embodiments of the present invention have been described herein with reference to the accompanying figures, the invention is not limited to those precise embodiments. A semiconductor device may comprise a different arrangement of elements and be formed by different methods and still come within the scope of the invention. While not all combinations of features have been described with respect to each illustrative embodiment, one skilled in the art will recognize that features described with respect to one illustrative embodiment can be utilized in other illustrative embodiments. One skilled in the art will recognize various other changes and modifications that may be made without departing from the scope of the appended claims.

What is claimed is:

1. A semiconductor device comprising:
an active layer;
a cladding layer; and
an electron blocking layer, the electron blocking layer at least partially disposed in a region between the active layer and the cladding layer and configured to form a potential barrier to a flow of electrons from the active layer toward the cladding layer;
wherein the electron blocking layer comprises two elements from Group III of the periodic table and an element from Group V of the periodic table, one of the two elements from Group III of the periodic table with a concentration profile having a first portion that gradually increases in concentration in a direction away from the active layer toward the cladding layer and having a second portion that gradually decreases in concentration between the first portion and the cladding layer.

2. The semiconductor device of claim 1, wherein the semiconductor device comprises a laser.

3. The semiconductor device of claim 1, wherein the semiconductor device comprises at least one of a light emitting diode, a photodetector and an optical coupler.

4. The semiconductor device of claim 1, wherein the electron blocking layer is disposed within a p-side waveguide layer formed between the active layer and the cladding layer.

5. The semiconductor device of claim 1, wherein the electron blocking layer adjoins the active layer.

6. The semiconductor device of claim 1, wherein the electron blocking layer adjoins the cladding layer.

7. The semiconductor device of claim 1, wherein the cladding layer comprises a stressed layer superlattice.

8. The semiconductor device of claim 1, wherein the potential barrier has a barrier height of at least about 50 millielectron volts.

9. The semiconductor device of claim 1, wherein at least one of the first and second portions of the concentration profile has a thickness that is equal to or greater than about ten nanometers.

10. The semiconductor device of claim 1, wherein the first and second portions of the concentration profile each have a thickness that is equal to or greater than about ten nanometers.

11. The semiconductor device of claim 1, wherein the concentration profile of the one of the two elements from Group III of the periodic table having the first portion and the second portion further comprises a third portion of the concentration profile, the third portion comprising a concentration of the one of the two elements that is substantially constant.

12. The semiconductor device of claim 1, wherein the first and second portions of the concentration profile abut one another resulting in an inflection point in the concentration profile.

13. The semiconductor device of claim 1, wherein the active layer comprises one or more quantum wells.

14. The semiconductor device of claim 1, further comprising two or more electrical contacts operative to provide electrical bias to cause the flow of electrical current through at least a portion of the semiconductor device.

15. The semiconductor device of claim 1, wherein the electron blocking layer comprises aluminum gallium nitride.

16. The semiconductor device of claim 1, wherein the one of the two elements from Group III of the periodic table with the concentration profile having the first portion and the second portion comprises aluminum.

17. The semiconductor device of claim 1, wherein the electron blocking layer is doped with magnesium.

18. A method of forming a semiconductor device, the method comprising the steps of:
forming an active layer;
forming a cladding layer; and
forming an electron blocking layer, the electron blocking layer at least partially disposed in a region between the active layer and the cladding layer and configured to form a potential barrier to a flow of electrons from the active layer toward the cladding layer;
wherein the electron blocking layer comprises two elements from Group III of the periodic table and an element from Group V of the periodic table, one of the two elements from Group III of the periodic table with a concentration profile having a first portion that gradually increases in concentration in a direction away from the active layer toward the cladding layer and having a second portion that gradually decreases in concentration between the first portion and the cladding layer.

19. An apparatus including:
a semiconductor device comprising:
an active layer;
a cladding layer;
an electron blocking layer, the electron blocking layer at least partially disposed in a region between the active layer and the cladding layer and configured to form a potential barrier to a flow of electrons from the active layer toward the cladding layer;
wherein the electron blocking layer comprises two elements from Group III of the periodic table and an element from Group V of the periodic table, one of the two elements from Group III of the periodic table with a concentration profile having a first portion that gradually increases in concentration in a direction away from the active layer toward the cladding layer and having a second portion that gradually decreases in concentration between the first portion and the cladding layer; and
control circuitry, the control circuitry operative to control the semiconductor device.

20. The apparatus of claim 19, wherein the apparatus comprises an optical disc drive.
